(19) United States
(12) Patent Application Publication
(10) Pub. No.: US 2011/0146795 A1
(43) Pub. Date: Jun. 23, 2011

(54) STRUCTURE AND PREPARATION OF CIGS-BASED SOLAR CELLS USING AN ANODIZED SUBSTRATE WITH AN ALKALI METAL PRECURSOR

(75) Inventors: Zue-Chin Chang, Taiping City (TW); Ching-Bin Lin, Taiping City (TW); Shih-Chang Liang, Taiping City (TW); Yen-Tseng Lin, Taiping City (TW); Yuan-Yuam Ko, Taiping City (TW); Chun-Yu Chang, Taiping City (TW)

(73) Assignee: NATIONAL CHIN-YI UNIVERSITY OF TECHNOLOGY, Taiping City (TW)

(21) Appl. No.: 12/769,303

(22) Filed: Apr. 28, 2010

(30) Foreign Application Priority Data
Dec. 22, 2009 (TW) 098144330

(51) Int. Cl. H01L 31/00; C25D 5/00

(52) U.S. Cl. 136/260; 136/252; 136/265; 205/122

(57) ABSTRACT

A template of a thin-film solar cell includes a substrate and an anodized layer. The anodized layer is formed on the substrate, and includes plural pores, wherein alkali halide precursor is filled into the pores for controlling diffused alkaline content. A preparation for fabricating a template of a thin-film solar cell includes steps of: a) providing a substrate; b) anodizing a surface of the substrate to form an anodized layer with plural pores; and c) filling alkali halide precursor into the pores.

### FIELD OF THE INVENTION

The present invention relates to a structure and preparation of CIGS-based solar cells, and more particularly to a structure and preparation of CIGS-based solar cells using an anodized substrate with an alkali metal precursor.

### BACKGROUND OF THE INVENTION

Recently, the ecological problems resulted from fossil fuels such as petroleum and coal have been greatly aware all over the world. Consequently, there are growing demands on clean energy. Among various alternative energy sources, a solar cell is expected to replace fossil fuels as a new energy source because it provides clean energy without depletion and is easily handled. A solar cell is a device that converts light energy into electrical energy.

There various solar cells in the market. Generally, a monocrystalline silicon solar cell has higher energy conversion efficiency and longer life, but is relatively costly. As such, the monocrystalline silicon solar cell is suitably used in power plants or traffic lighting facilities. In addition, amorphous silicon solar cells, cadmium telluride solar cells, indium gallium arsenide solar cells or gallium arsenide solar cells have wider scope of application. Generally, the energy conversion efficiency of a solar cell is dependent on the band gap of silicon material, optical absorption coefficient, carrier transport characterization, and the like. In other words, for producing a high conversion efficiency solar cell, the type of material and the film coating process should be taken into consideration.

In 1977, University of Maine first disclosed a copper-indium-selenide (CIS) thin-film solar cell. For increasing conversion efficiency, a copper-indium-gallium-selenide (CIGS) thin-film solar cell was disclosed later. Since the thickness of the photoelectric conversion layer of the CIGS thin-film solar cell is very thin (about several micrometers), the material cost is reduced and the energy required for fabricating the solar cell is saved. As the thickness of the photoelectric conversion layer is reduced, the optical absorption ability of the CIGS material is enhanced. Generally, the CIGS thin-film solar cell has a conversion efficiency of about 25˜30%, which is much higher than the monocrystalline silicon solar cell. The commercial CIGS module is higher by about 10˜12%. Moreover, as the composition of the CIGS semiconductor is changed in the thickness direction, the absorption wavelength spectrum is broadened and thus the conversion efficiency of the solar cell is enhanced. In addition, the CIGS thin-film solar cell is subject to degradation under irradiation of light beams or radioactive rays more difficultly than the silicon solar cell. In other words, the CIGS thin-film solar cell has longer life to meet the requirements of space exploration. Moreover, since the CIGS semiconductor is a direct-gap semiconductor, the CIGS thin-film solar cell has good optical absorption properties and superior optical absorption coefficient. Due to the above advantages, recent researches are focused on development of CIGS thin-film solar cells.

FIG. 1 is a schematic view illustrating a CIGS thin-film solar cell according to the prior art. As shown in FIG. 1, the CIGS thin-film solar cell comprises a glass substrate 11, a back electrode 12, a CIGS absorber layer 13, a buffer layer 14, an intrinsic oxide layer 15, a transparent conductive film 16, an anti-reflective film 17 and an external electrode 18. Since the glass substrate 11 contains elemental sodium (Na), the elemental sodium may diffuse into the CIGS absorber layer 13 during the co-evaporation process. As such, the solar cell conversion efficiency, fill factor, open-circuit voltage and CIGS conductivity are increased, but the CIGS grain size is reduced. For achieving the above benefits, the concentration of sodium should be controlled within an optimal range. As known, no addition of sodium may reduce the conversion efficiency of the solar cell by about 2%˜3%.

FIG. 2 is a schematic view illustrating another CIGS thin-film solar cell according to the prior art. As shown in FIG. 2, the CIGS thin-film solar cell comprises a sodium-free substrate 21, a back electrode 22, a precursor sodium fluoride layer 26, a CIGS absorber layer 23, a buffer layer 24, an intrinsic oxide layer 251, a transparent conductive film 152, an anti-reflective film 253 and an external electrode 254. The sodium-free substrate 21 is made of for example sodium-free polyimide (PI) or stainless steel. The configurations of the buffer layer 24, the intrinsic oxide layer 251, the transparent conductive film 252, the anti-reflective film 253 and the external electrode 254 are similar to those shown in FIG. 1, and are not redundantly described herein. The sodium fluoride layer 26 is arranged over the back electrode 22 for providing suitable sodium concentration to the CIGS absorber layer 23. After the CIGS thin-film solar cell is finished, the precursor sodium fluoride layer on the polyimide or stainless steel substrate needs to be completely used up. The residual of the precursor sodium fluoride layer may form a recombination center in the region between the CIGS absorber layer and the back electrode. As such, the conversion efficiency of the solar cell is largely reduced.

The substrate used in the CIGS thin-film solar cell usually has flexibility. In a case that a glass substrate is used, the slim-type glass substrate is feasible. The slim-type glass substrate, however, is costly and readily damaged or scraped during the manufacturing process. Although the polyimide substrate is flexible, the polyimide substrate can only withstand a temperature up to 300° C. In the post-treatment requiring high temperature (e.g. CIGS co-evaporation or sputtering at 300˜500° C.), the polyimide substrate is readily deformed because of thermal stress, or the polyimide substrate is detached from the back electrode. In other words, the yield is reduced. In a case that a flexible stainless steel substrate is used, a problem of causing leakage current on the back electrode occurs because the insulation is poor.

For solving the above problems, U.S. Pat. No. 5,626,688 disclosed a CIGS thin-film solar cell with a diffusion barrier layer. FIG. 3 is a schematic view illustrating a CIGS thin-film solar cell described in U.S. Pat. No. 5,626,688. As shown in FIG. 3, the CIGS thin-film solar cell comprises a glass substrate 31, a diffusion barrier layer 37, a back electrode 32, a precursor sodium fluoride layer 36, a CIGS absorber layer 33, a buffer layer 34, an intrinsic oxide layer 351, a transparent conductive film 352, an anti-reflective film 353 and an external electrode 354. The diffusion barrier layer 37 is arranged between the glass substrate 31 and the back electrode 32. The diffusion barrier layer 37 is made of aluminum oxide. The use of the diffusion barrier layer can avoid the problem of causing leakage current. Since no sodium is contained in the stainless steel substrate, the stainless steel substrate fails to provide and control desired sodium content. In other words, the stainless steel substrate is not feasible. In a case that the glass substrate 31 contains sodium, the diffusion barrier layer 37 may hinder elemental sodium from diffusing into the CIGS absorber layer 33. As such, the grain growth is usually insufficient and the conversion efficiency is reduced. Since the diffusion barrier layer 37 is formed on the glass substrate 31 by magnetron sputtering, the quality of the diffusion barrier layer 37 is not satisfied but the fabricating cost is relatively higher. In other words, this conventional CIGS thin-film solar cell needs to be further improved.

From the above discussions, the slim-type substrate, the polyimide substrate and the stainless steel substrate have respective drawbacks. The conventional CIGS thin-film solar cells fail to effectively control the content of sodium diffusing into the CIGS absorber layer. In addition, the fabricating process is complicated and costly.

For obviating the drawbacks encountered from the prior art, there is a need of providing a structure and preparation of CIGS-based solar cells using an anodized substrate with an alkali metal precursor.

### SUMMARY OF THE INVENTION

It is an object of the present invention to provide a structure and preparation of CIGS-based solar cells using an anodized substrate with an alkali metal precursor. The provided structure and preparation of CIGS-based solar cells is capable of controlling a desired content of alkali metal to diffuse into a CIS/CIGS absorber layer, and preventing the possible contamination from influencing the CIS/CIGS absorber layer. The fabricating preparation is simple and cost-effective.

In accordance with an aspect of the present invention, there is provided a template of a thin-film solar cell. The template includes a substrate and an anodized layer. The anodized layer is formed on the substrate, and includes plural pores, wherein alkali halide precursor is filled into the pores for controlling diffused alkaline content.

In accordance with another aspect of the present invention, there is provided a preparation for fabricating a template of a thin-film solar cell. The preparation includes steps of: a) providing a substrate; b) anodizing a surface of the substrate to form an anodized layer with plural pores; and c) filling alkali halide precursor into the pores.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic view illustrating a CIGS thin-film solar cell according to the prior art;

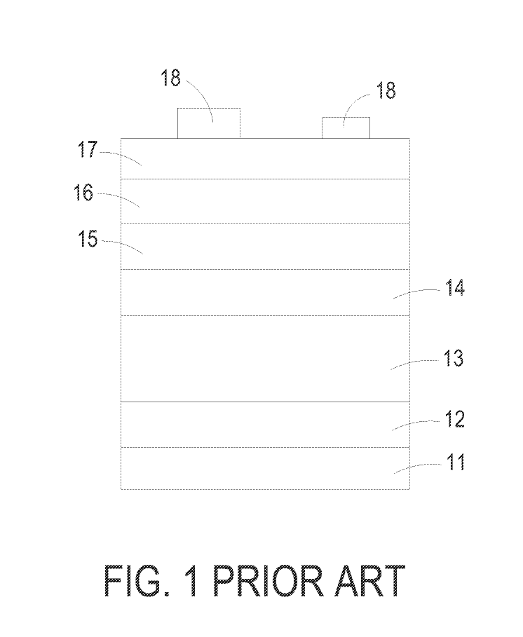

FIG. 2 is a schematic view illustrating another CIGS thin-film solar cell according to the prior art;

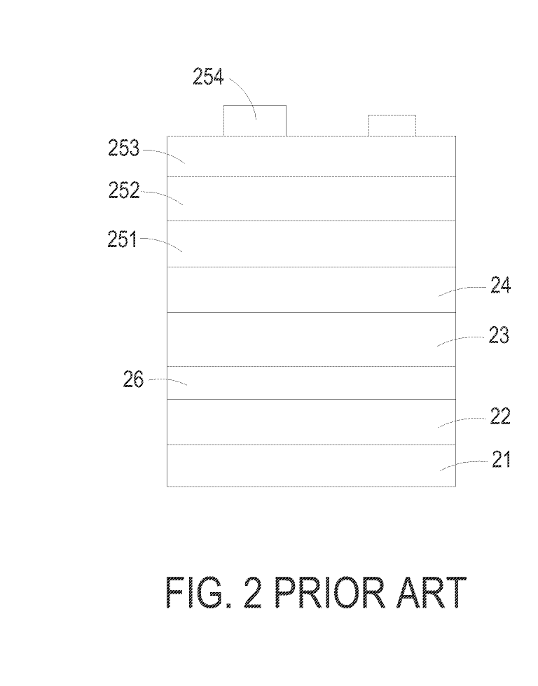

FIG. 3 is a schematic view illustrating another CIGS thin-film solar cell according to the prior art;

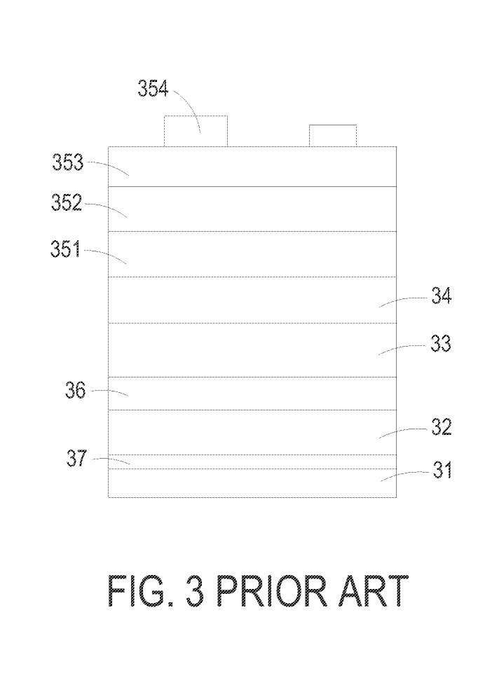

FIG. 4 is a schematic view illustrating an anodized substrate with alkali halide precursor to be used in a thin-film solar cell according to an embodiment of the present invention;

FIGS. 5A-5E are schematic views illustrating a preparation for fabricating an anodic aluminum oxide (AAO) substrate; and

FIG. 6 is a schematic view illustrating a CIGS thin-film solar cell according to an embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

The present invention relates to an anodized template of a thin-film solar cell, and a preparation for fabricating the anodized template. The anodized template comprises a porous heat-resistant substrate and anodized layer. According to the anodized template and the preparation for fabricating the anodized template, fixed quantity of alkali halide precursor previously filled in the substrate may diffuse into the CIS/CIGS absorber layer during the CIS/CIGS absorber layer is formed. As a consequence, the CIS/CIGS absorber layer will contain a desired content of alkali metal. Moreover, the possible contamination originating from the substrate may be isolated by the anodized layer of the anodized template.

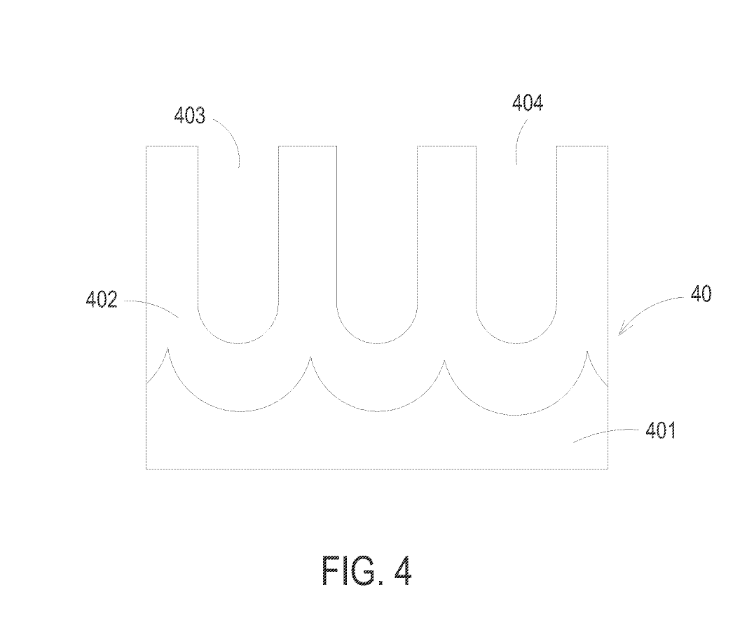

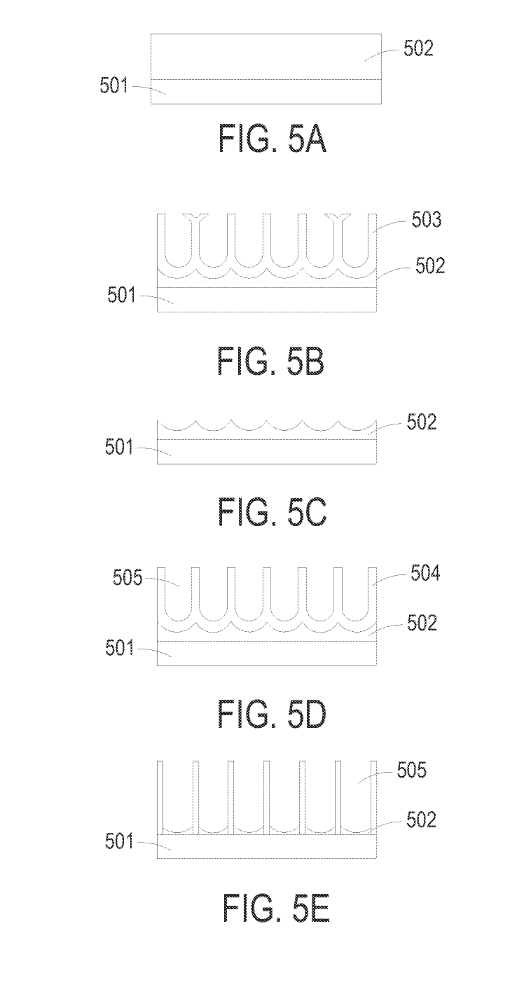

FIG. 4 is a schematic view illustrating an anodized template with alkali halide precursor to be used in a thin-film solar cell according to an embodiment of the present invention. As shown in FIG. 4, the anodized template 40 comprises a substrate 401 and an anodized layer 402. The anodized layer 402 is formed on the substrate 401, and comprises plural pores 403. Fixed quantity of alkali halide precursor 404 is filled into the pores 403 for providing desired content of alkali metal to the absorber layer (see FIG. 5). The anodized layer 402 is made of anodic aluminum oxide (AAO). The pores 403 are made of hexagonal porous aluminum oxide. The pores 403 are uniform and perfect pores with a pore diameter of from 14˜300 nm and a pore density of from 10⁹˜10¹²/cm².

A preparation for fabricating the anodized template comprises steps of: a) providing a substrate 401; b) anodizing the surface of the substrate 401 to form an anodized layer 402 with plural pores 403; and c) filling alkali halide precursor 404 into the pores 403. In practice, the anodizing procedure may be carried out in a single-stage manner or a two-stage manner. The alkali halide precursor 404 filled into the pores 403 has fixed quantity, thereby providing desired content of alkali metal to the CIS/CIGS absorber layer.

Hereinafter, a process for fabricating an anodic aluminum oxide (AAO) template will be illustrated with reference to FIGS. 5A˜5E. Firstly, as shown in FIG. 5A, a high-purity (99.9%) aluminum layer 502 is formed on a substrate 501. The substrate 501 is made of aluminum oxide. Prior to anodizing, the aluminum layer 502 is annealed in a vacuum of 10⁻³ Pa at 550° C. for 10 hours to remove the residual stress and obtain homogenous conditions for pore growth over a large area. Then, an anodizing procedure is carried out under a constant cell voltage 42V in a 0.35 M oxalic acid (H₂C₂O₄) solution at 0° C. for 12 hours. As such, an electrochemical reaction is performed on the surface of the aluminum layer 502 to form a sacrificial aluminum oxide layer 503 (see FIG. 5B). Then, as shown in FIG. 5C, the sacrificial aluminum oxide layer 503 is removed by a mixture of 6.5 wt % phosphoric acid (H₃PO₄) and 2.0 wt % chromic acid (H₂CrO₄) at 65° C. for 122 hours. The anodizing procedure is carried out again under a constant cell voltage 42V in a 0.35 M oxalic acid (H₂C₂O₄) solution at 0° C. for 24 hours. As such, an anodized layer 504 is produced (see FIG. 5D). The residuals on the pore array 505 of the anodized layer 504 are removed in 1.2 M copper chloride (CuCl₂) solution. A subsequent etching treatment is carried out in a 6 wt % oxalic acid (H₂C₂O₄) at 23° C. for 2 hours to remove the anodized layer 504 on the bottom side of the pore array 505 and a portion of the aluminum layer 502. As such, the pore array 505 of the AAO template is slightly widened.

The alkali halide precursor to be filled into the pores 505 is prepared as aqueous solution. For example, sodium fluoride (NaF) solution is prepared by adding 4.13 grams of sodium fluoride to 100 grams of pure water at 25° C.; and lithium fluoride (LiF) is prepared by adding 2.7 grams of lithium fluoride to 1,000 grams of pure water at 20° C.

In some embodiment, the process for fabricating an anodic aluminum oxide (AAO) template may be modified according to the practical requirements. For example, the anodizing procedure is carried out in a single-stage manner. Firstly, as shown in FIG. 5A, an aluminum layer 502 is formed on a substrate 501. Prior to anodizing, the aluminum layer 502 is degreased, etched in alkaline solution and rinsed in distilled water, and then electropolished to achieve a smooth surface. During the electropolishing process, it is necessary to immerse the samples in concentrated acid or alkaline solution for several minutes to remove the oxide layer formed from electrolysis. The surface of the aluminum layer 502 is rinsed in distilled water and then transferred to a nitrogen environment. The resultant clean aluminum layer 502 is anodized at constant potential in phosphoric acid (100 V, 0° C., Pt sheet as a counter electrode). As such, an electrochemical reaction is performed on the surface of the aluminum layer 502 to form an anodized layer 504 on the aluminum layer 502 (see FIG. 5D). Then, the whole structure is put into saturated mercury chloride (HgCl₂) solution to the residuals of the pores 505. The bottom sides of the pores 505 are rinsed with distilled water and then immersed in 5% phosphoric acid (H₃PO₄) solution for about 30 min at 30° C. As a consequence, the pores 505 of the AAO template are produced (see FIG. 5E). The pores 550 has a pore diameter of 110±7 nm and a pore density of about 10¹⁰—10¹¹ cm⁻².

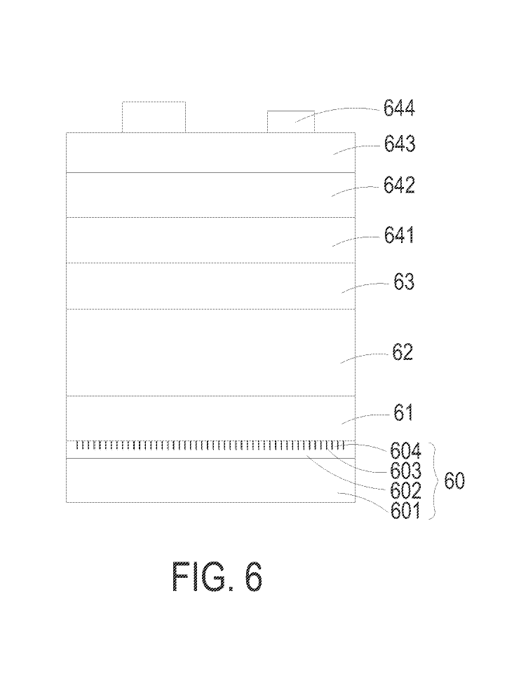

FIG. 6 is a schematic view illustrating a CIGS thin-film solar cell according to an embodiment of the present invention. As shown in FIG. 6, the CIGS thin-film solar cell comprises a template 60, a back electrode 61, an absorber layer 62 and a buffer layer 63. The template 60 is fabricated by the above-mentioned process. The template 60 comprises a substrate 601 and an anodized layer 602 with plural pores 603, wherein alkali halide precursor 604 is filled into the pores 603. The back electrode 61 is formed on the anodized layer 602. The absorber layer 62 is formed on the back electrode 61. The alkali metal of the may diffuse into the absorber layer 62. The buffer layer 63 is formed on the absorber layer 62. The alkali halide precursor 604 is selected from sodium fluoride (NaF), lithium fluoride (LiF), sodium sulfide (Na₂S) or sodium selenide (Na₂Se). In an embodiment, molybdenum is sputtered on the anodized layer 602 of a 150 μm-template 60 at 300° C. by 2 kW DC magnetron sputtering. As such, a back electrode 61 with bi-layered molybdenum is produced. The absorber layer 62 is prepared by simultaneous evaporation of four elements copper (Cu), indium (In), gallium (Ga) and selenide (Se) in a three-stage evaporation process. In the first stage, In, Ga and Se element sources are evaporated on the back electrode 61 at 400° C. to form an (In,Ga)₂Se₃ layer with a thickness of 2 μm. In the second stage, Cu and Se are added and reacted directly with the (In,Ga)₂Se₃ layer at 560° C. to form a Cu-rich CIGS layer. In the third stage, In, Ga and Se elements are evaporated on the CIGS layer in order to convert into an (In,Ga)-rich CIGS composition. The total thickness of the absorber layer 62 is about 25 μm. Then, a cadmium sulfide (CdS) or zinc sulfide (ZnS) buffer layer 63 is formed on the absorber layer 62 by chemical bath deposition (CBD) and RF magnetron sputtering. The buffer layer 63 has a thickness of about 50 nm.

A multi-layered transparent electrode structure is formed on the buffer layer 63. For example, the multi-layered transparent electrode structure comprises a 70 nm undoped zinc oxide layer/400 nm aluminum-doped zinc oxide layer/100 nm magnesium fluoride layer/2 μm aluminum/nickel alloy layer. Firstly, an undoped zinc oxide layer 641 is formed on the buffer layer 63 by RF magnetron sputtering. Then, an aluminum-doped zinc oxide layer 642 is deposited on the undoped zinc oxide layer 641 by RF magnetron sputtering. Then, a magnesium fluoride layer 643 is deposited on the aluminum-doped zinc oxide layer 642 by DC sputtering. Afterwards, an aluminum/nickel alloy layer 644 is deposited on the magnesium fluoride layer 643 by thermal evaporation. As a consequence, an intrinsic oxide layer, a transparent conductive film, an anti-reflective film and an external electrode are successively formed.

The thin-film solar cell of the present invention has excellent performance. For example, for a 16 cm² of active area, the open-circuit voltage is increased to 689 mV, the short-circuit current density reaches 30 mA/cm², the conversion efficiency reaches 14.5%, and the filling factor is increased to 67%.

In the above embodiments, the substrate is made of aluminum or aluminum oxide. Nevertheless, the substrate may be made of any other porous heat-resistant material such as a ceramic material or titanium alloy.

From the above description, the thin-film solar cell of the present invention has an anodized template with alkali halide precursor. According to the anodized template and the preparation for fabricating the anodized template, fixed quantity of alkali halide precursor previously filled in the substrate may diffuse into the CIS/CIGS absorber layer during the CIS/CIGS absorber layer is formed. As a consequence, the CIS/CIGS absorber layer will contain a desired content of alkali metal. Moreover, the possible contamination originating from the substrate may be isolated by the anodized layer of the anodized template.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A template of a thin-film solar cell, said template comprising:
a substrate; and
an anodized layer formed on said substrate, and comprising plural pores, wherein alkali halide precursor is filled into said pores for controlling diffused alkaline content.

2. The template of a thin-film solar cell according to claim 1 wherein said anodized layer is made of anodic aluminum oxide (AAO), and said pores are made of hexagonal porous aluminum oxide.

3. The template of a thin-film solar cell according to claim 2 wherein said pores are uniform and perfect pores with a pore diameter of from 14˜300 nm and a pore density of from 10⁹˜10¹²/cm².

4. The template of a thin-film solar cell according to claim 1 wherein said alkali halide precursor is selected from sodium fluoride (NaF), lithium fluoride (LiF), sodium sulfide (Na₂S) or sodium selenide (Na₂Se).

5. The template of a thin-film solar cell according to claim 1 wherein said substrate is made of a porous heat-resistant material.

6. The template of a thin-film solar cell according to claim 1 wherein said substrate is made of aluminum or aluminum oxide.

7. The template of a thin-film solar cell according to claim 1 wherein said substrate is made of a ceramic material or titanium alloy.

8. The template of a thin-film solar cell according to claim 1 wherein said thin-film solar cell further comprises:
a back electrode formed on said anodized layer;
an absorber layer formed on said back electrode;
a buffer layer formed on said absorber layer; and
a transparent conductive film formed on said buffer layer,
wherein during said back electrode and said absorber layer are formed, alkali metal of said alkali halide precursor diffuses into said absorber layer, thereby providing a desired content of alkali metal to said absorber layer.

9. The template of a thin-film solar cell according to claim 8 wherein fixed quantity of alkali halide precursor is filled into said pores for providing desired content of alkali metal to said absorber layer.

10. The template of a thin-film solar cell according to claim 8 wherein said back electrode has a bi-layered molybdenum structure, which is produced by sputtering.

11. The template of a thin-film solar cell according to claim 8 wherein said absorber layer is a copper-indium-selenide (CIS) absorber layer or a copper-indium-gallium-selenide (CIGS) absorber layer.

12. The template of a thin-film solar cell according to claim 8 wherein said buffer layer is made of cadmium sulfide (CdS) or zinc sulfide (ZnS).

13. A preparation for fabricating a template of a thin-film solar cell, said preparation comprising steps of:
a) providing a substrate;
b) anodizing a surface of said substrate to form an anodized layer with plural pores; and
c) filling alkali halide precursor into said pores.

14. The preparation according to claim 13 wherein said anodized layer is made of anodic aluminum oxide (AAO), and said pores are made of hexagonal porous aluminum oxide.

15. The preparation according to claim 13 wherein said step (b) further comprises sub-steps of:
b1) forming an aluminum layer;
b2) performing an electrochemical reaction on said aluminum layer, thereby forming a sacrificial aluminum oxide layer; and
b3) removing said sacrificial aluminum oxide layer to expose said aluminum layer; and
b4) performing an electrochemical reaction on said aluminum layer, thereby forming said poles of said anodized layer.

16. The preparation according to claim 13 wherein said pores are uniform and perfect pores with a pore diameter of from 14˜300 nm and a pore density of from 10⁹˜10¹²/cm².

17. The preparation according to claim 13 wherein said alkali halide precursor is selected from sodium fluoride (NaF), lithium fluoride (LiF), sodium sulfide (Na₂S) or sodium selenide (Na₂Se).

18. The preparation according to claim 13 wherein said substrate is made of a porous heat-resistant material.

19. The preparation according to claim 13 wherein said substrate is made of aluminum or aluminum oxide.

20. The preparation according to claim 13 wherein said substrate is made of a ceramic material or titanium alloy.
